(19) United States
(12) Patent Application Publication
(10) Pub. No.: US 2017/0343037 A1
(43) Pub. Date: Nov. 30, 2017

(54) Reclosable Adhesive Strip

(71) Applicants: Henkel AG & Co. KGaA, Duesseldorf (DE); Henkel IP & Holding GmbH, Duesseldorf (DE); INSTITUT CATALÀ DE NANOCIÈNCIA I NANOTECNOLOGIA (ICN2), Bellaterra (ES)

(72) Inventors: Jose Garcia Miralles, Duesseldorf (DE); Achille Francone, Barcelona (ES); Nikolaos Kehagias, Thessaloniki (GR); Fouad Salhi, Barcelona (ES); Dina Augusta Simones Marques, Agueda (PT)

(21) Appl. No.: 15/532,710

(22) PCT Filed: Dec. 3, 2015
(86) PCT No.: PCT/EP2015/078572

§ 371 Date: Jun. 2, 2017

(30) Foreign Application Priority Data
Dec. 5, 2014 (EP) 14196535.0

(51) Int. Cl. F16B 47/00; C08J 5/12; F16B 5/07; G03F 7/00

(52) U.S. Cl. CPC F16B 47/003; G03F 7/0015; G03F 7/0002; C08J 5/12; F16B 5/07; C08J 2335/02

(57) ABSTRACT

An adhesive strip including a support, a substrate and a plurality of fixing elements protruding from the substrate. The fixing elements and substrate are formed from a photo-curable adhesive composition that includes component A: a (meth)acrylate monomer or oligomer having at least two (meth)acrylate groups and having an average molecular weight M_{w} from 700 g/mol to 7000 g/mol; component B: a (meth)acrylate monomer or oligomer having at least two (meth)acrylate groups and having an average molecular weight M_{w} equal or greater than 150 g/mol and less than 700 g/mol; component C: a photoinitiator; and component D: a polythiol. A reclosable fastener can be formed with the adhesive strip such as a reclosable male-to-male adhesive based on a fastener having two adhesive strips.

### TECHNICAL FIELD OF THE INVENTION

The present invention relies on an adhesive strip comprising a support, a substrate and a plurality of fixing elements protruding from said substrate, wherein said fixing elements and said substrate are formed from a photo-curable adhesive composition.

### BACKGROUND OF THE INVENTION

A flexible and dry attachment between two surfaces can be achieved in two different ways. One way is to bond a one-side-patterned surface (containing micro-nano hierarchical structures, as in the case of “gecko-inspired adhesive”) with a smooth surface. The other way is to put into contact two one-side-patterned surfaces. In the latter way, depending on the type of the bonding structures on the attached surfaces, it is possible to distinguish two different systems: male-to-female or male-to-male.

A male-to-female attachment is provided by two surfaces containing different structures (male on one side and female on the other) that can be interlocked ensuring an effective fastening system. This is the case for example in the hook-and-loop fasteners.

A male-to-male attachment is provided by two surfaces containing the same structures (male on one side and male on the other). This type of fastener is sometimes referred to as “self-engaging”, particularly, when the fastener elements of each surface are of a similar size and shape. These self-engaging fasteners can be also defined as flexible and reclosable fasteners. Looking at the geometry of the male-to-male reclosable fasteners, the attaching (fixing) elements generally present over-hanging structures. This is the most common solution in order to bond two surfaces with high values of peel/shear force.

Many self-engaging fastener (SEF) products utilise mushroom type fastener elements. By the term ‘mushroom type fastener’ is meant fasteners having heads that overhang in multiple directions. Such mushroom fastener elements are arranged with sufficient density, in order for edges of mating mushrooms snap past each other during engagement. Alternatively, hooked type fastener elements can be used, wherein fastener elements have different shapes and dimensions.

As main drawback of attaching elements with over-hanging structures, is that a force ripple is required for attachment and detachment—in such way the peel or shear capability cannot be tuned and controlled.

Self-engaging fastener products are considered to exhibit high shear and tension resistance, and they require higher force for engagement, than typical hook-and loop fasteners. It is common to experience a peel force ripple and associated noise during disengagement of SEF products by peel, as individual fastener elements snap out of engagement.

Several examples of attaching structures without over-hanging profile exist in the prior art. Solid tapered elements with trapezoidal shaped cross-section, having at least one side inclined with a specific angle are well described and used.

Mating elements with trapezoidal shaped cross-section are also described and used in the past. Both lateral sides are inclined with a specific angle and contain a plurality of microprotrusions, whose height and width are no more than 400 microns. The disengagement force is related to the number of interlocking engaged microprotrusions.

A clasp with two overlapping members, each one having a plurality of prongs extending from one side is also described and used. The prongs present enlarged portions interlocking engaging reduced portions on the complementary member.

Flexible, reclosable fasteners have been fabricated in the past by using a continuous manufacturing process, called extrusion. In the extrusion process, a thermoplastic polymer is melted first, and subsequently formed into a continuous fastener using a die or a mould, followed by a cooling step before collecting the final product into a roll.

An example of extrusion process is described in the system, where mushroom type of hook strips are fabricated by using a rotating mould. The mould is cooled at the walls of the evacuated cavities to cause the melted resin to become molecularly oriented while it is filling the cavities. Subsequently, the injected resin requires time to solidify, before moving to next steps. The cooling time represents the main bottleneck in such a process.

As described above, the flexible reclosable fasteners are commonly fabricated using a continuous extrusion process. The main limitations of this manufacturing process are the minimum extrudable dimension (tens of micrometer), high pressure (tens of MPa) and high temperature (100-300° C.) involved in the process due to the viscosity of thermoplastic polymers (thousands of Pa·s) and the need for a cooling step.

In addition, currently commercially available flexible reclosable fasteners have attaching elements with an over-hanging profile (mostly mushroom, hook shape), and requires a force ripple for attachment/detachment. In this way the peel/shear capability cannot be tuned and controlled and physical dimensions are hundreds of microns (higher than 500 μm).

Therefore, there is a need for the process to take into consideration all mentioned drawbacks in order to produce fastener elements with smaller dimensions, which could provide more flexibility and versatility for the implementation of such reclosable fastener on flexible and rigid packages.

### SHORT DESCRIPTION OF THE FIGURES

FIG. 1 illustrates some of the preferred shapes of the fixing elements according to the present invention.

FIG. 2 illustrates one embodiment of the process according to the present invention.

FIG. 3 illustrates general structure of the adhesive strips according to the present invention.

FIG. 4 illustrates how the flexible working stamp is produced.

FIG. 5 illustrates T-Peel test results of pillar shaped fixing elements according to the present invention.

FIG. 6 illustrates a dynamic tensile shear test results of pillar shaped fixing elements according to the present invention.

FIG. 7 illustrates mechanical properties (tensile strength and elongation) for compositions 2a-2d.

FIG. 8 illustrates mechanical properties (tensile strength and elongation) for compositions 2g-2h.

FIG. 9 illustrates comparative T-Peel test results.

FIG. 10 illustrates enlargement of FIG. 9.

FIG. 11 illustrates comparative dynamic peel test results.

FIG. 12 illustrates enlargement of FIG. 11.

### SUMMARY OF THE INVENTION

The present invention relates to an adhesive strip comprising a support, a substrate and a plurality of fixing elements protruding from said substrate, wherein said fixing elements and said substrate are formed from a photo-curable adhesive composition comprising component A: a (meth)acrylate monomer or oligomer comprising at least two (meth)acrylate groups and having an average molecular weight M_{w} from 700 g/mol to 7000 g/mol, component B: a (meth)acrylate monomer or oligomer comprising at least two (meth)acrylate groups and having an average molecular weight M_{w} equal or greater than 150 g/mol and less than 700 g/mol, component C: a photoinitiator, and component D: a polythiol.

The present invention also relates to the use of an adhesive strip according to the present invention as a reclosable fastener.

In addition, the present invention relates to a reclosable male-to-male adhesive based on fastener comprising two adhesive strips according to present invention.

The present invention also encompasses a continuous process to prepare an adhesive strip according to the present invention comprising steps of: i) providing a support suitable for nanoimprint lithography processes or roll to roll printing processes; ii) applying sufficient amount of the photo-curable adhesive composition according to the present invention at least part of the support provided on step (i); iii) providing a stamp suitable for nanoimprint lithography processed and imprinting the photo-curable adhesive composition applied to the support in step (ii) with the stamp or providing a flexible working stamp around rotating metallic roll and printing the photo-curable adhesive composition applied to the support in step (ii) with the flexible working stamp; iv) simultaneously with the step (iii), the support is irradiated by using UV light; and said support containing the cured microstructured adhesive composition is de-moulded from the stamp or from the flexible working stamp.

### DETAILED DESCRIPTION OF THE INVENTION

In the following passages the present invention is described in more detail. Each aspect so described may be combined with any other aspect or aspects unless clearly indicated to the contrary. In particular, any feature indicated as being preferred or advantageous may be combined with any other feature or features indicated as being preferred or advantageous.

In the context of the present invention, the terms used are to be construed in accordance with the following definitions, unless a context dictates otherwise.

As used herein, the singular forms “a”, “an” and “the” include both singular and plural referents unless the context clearly dictates otherwise.

The terms “comprising”, “comprises” and “comprised of” as used herein are synonymous with “including”, “includes” or “containing”, “contains”, and are inclusive or open-ended and do not exclude additional, non-recited members, elements or method steps.

The recitation of numerical end points includes all numbers and fractions subsumed within the respective ranges, as well as the recited end points.

All percentages, parts, proportions and the like mentioned herein are based on weight unless otherwise indicated.

When an amount, a concentration or other values or parameters is/are expressed in form of a range, a preferable range, or a preferable upper limit value and a preferable lower limit value, it should be understood as that any ranges obtained by combining any upper limit or preferable value with any lower limit or preferable value are specifically disclosed, without considering whether the obtained ranges are clearly mentioned in the context.

All references cited in the present specification are hereby incorporated by reference in their entirety.

Unless otherwise defined, all terms used in disclosing the invention, including technical and scientific terms, have the meaning as commonly understood by one of the ordinary skill in the art to which this invention belongs to. By means of further guidance, term definitions are included to better appreciate the teaching of the present invention.

The present invention discloses an adhesive strip comprising a support, a substrate and a plurality of fixing elements protruding from said substrate, wherein said fixing elements and said substrate are formed from a photo-curable adhesive composition comprising component A: a (meth)acrylate monomer or oligomer comprising at least two (meth)acrylate groups and having an average molecular weight M_{w} from 700 g/mol to 7000 g/mol, component B: a (meth)acrylate monomer or oligomer comprising at least two (meth)acrylate groups and having an average molecular weight M_{w} greater than 150 g/mol and less than 700 g/mol, component C: a photoinitiator, and component D: a polythiol.

The adhesive strip according to the present invention can be used as a reclosable fastener and it can form a male-to-male reclosable fastener. Said fastener contains two adhesive strips each comprising a plurality of fixing elements having one-level structure protruding from the substrate or plurality of fixing elements having two-level structure protruding from the substrate. The first level structure has physical dimensions of few hundreds microns, while the second level structure, when present, has physical dimensions around tens of microns. Such configuration enables a controlled attachment and detachment, without any force ripple. As consequence, the peel and shear capability is successfully tuned and controlled.

Each aspect of the present invention will be discussed in details.

An adhesive strip according to the present invention comprises a support. Suitable support for use in the present invention is made from flexible material, semi-flexible material or rigid material. Any material, which is compatible with a photo-curable adhesive composition, used to form a substrate and fixing elements protruding from said substrate and compatible with the process forming an adhesive strip. Suitable material for use as a support herein can be for example plastic, thermoplastic polymer material, paper or cardboard.

Preferably, the material for use in the present invention as a support is a thermoplastic polymer selected from the group consisting of polymethyl methacrylates, polybutyl methacrylates, polyethylene terephthalates, polybutylene terephthalates, polyvinylidene fluorides, polyvinyl chlorides, polyesters, polyolefins, acrylonitrile ethylene propylene diene styrene copolymers (A-EPDM), polyetherimides, polyether ketones, polyphenylene sulphides, polyphenylene ethers and mixtures thereof. Preferably, support made of polyethylene terephthalates.

The thickness of the support is preferably from 1 μm to 500 μm, preferably from 10 μm to 300 μm, more preferably from 15 μm to 200 μm and most preferably from 20 μm to 150 μm.

If the support is too thin, mechanical deformation may be caused by the deposited composition. In addition, and for example if the support is made of PET film and it is too thin it may result in non-filled cavities in the stamp due to the low tension imprint.

An adhesive strip according to the present invention comprises a substrate, which is on top of the support and a plurality of fixing elements protruding from said substrate.

The substrate can be shaped in any suitable form. It is for example possible to provide a plane surface with a flat lower and in opposite direction a flat upper surface, wherein said fixing elements protrudes from said upper surface.

Substrate according to present invention may comprise hierarchical structures on at least parts of the surface of the substrate adjacent to at least one fixing element. In one embodiment, the substrate may comprise hierarchical structures on the surface of the substrate adjacent to said plurality of said fixing elements.

By the term “hierarchical structures” is meant herein the second level of structures (micro structures) in the fixing elements or on the substrate. Hierarchical structures are arranged in predefined manner and they have a well-defined level/plane to which they belong to.

Fixing elements can be shaped in any suitable form. They can have any suitable base and/or cross section. It is for example possible to provide fixing elements with round or elliptical bases and/or cross section. It is also possible to choose a triangular, rectangular, square or polygonal shape. It is furthermore imaginable that the cross section changes lengthwise. The distal section, which is located opposite to said base, which is in turn located in the level of said substrate, can also be shaped in any suitable form. It is possible to provide a flat upper surface, running in parallel or angularly compared to the surface of said substrate. It is also possible use a dome shaped distal section.

Fixing element according to present invention may comprise hierarchical structures on at least parts of the outer surface of at least one fixing element and/or on at least parts of the surface of the substrate adjacent to at least one fixing element.

In one embodiment, hierarchical structures are provided on at least parts of the outer surface of each fixing element and/or on at least parts of the surface of the substrate adjacent to each fixing element.

Fixing element may comprise an upper surface at the distal section, which may be equipped with hierarchical structures. When using a dome-shaped distal section, it is also possible to cover at least partly the dome shaped distal section with said hierarchical structures. In addition or as an alternative, the fixing element may comprise side surfaces, which may be equipped with a hierarchical structure.

Fixing element according to the present invention have a height in the range of 150 μm to 1000 μm, preferably from 150 μm to 750 μm, more preferably from 150 μm to 500 μm, and most preferably from 150 μm to 400 μm.

If the fixing element height is less than 1 μm it produces gecko effect structures and these are in the nanometer scale, and therefore, there will not be any mechanical attachments. On the other hand if the height of the fixing element is too high, it no longer serve the purpose of micro level fixing structure, and moreover, fixing elements in such a size would be difficult to produce via the methods according to the present invention.

By the height of a fixing element is meant herein the distance between the topmost point of a fixing element in distal direction and the surface of the substrate adjacent to the respective fixing element orthogonal to said surface.

Fixing elements according to the present invention have a width in the range of 100 μm to 1000 μm, preferably from 120 μm to 750 μm, more preferably from 120 μm to 500 μm and most preferably from 120 μm to 400 μm.

By the width of a fixing element is meant herein the greatest length of a cross section of a fixing element parallel to the surface of the substrate adjacent to said fixing element.

Preferably, the aspect ratio of the fixing elements is from 1 to 2, preferably about 1.5.

It is not feasible to produce fixing elements having aspect ratio greater than 3. This means that if fixing elements according to the present invention have a height of 100′s of microns then the diameter of the fixing elements must be in the same range. Furthermore, mechanical stability of fixing elements having aspect ratio greater than 3 would not be ideal.

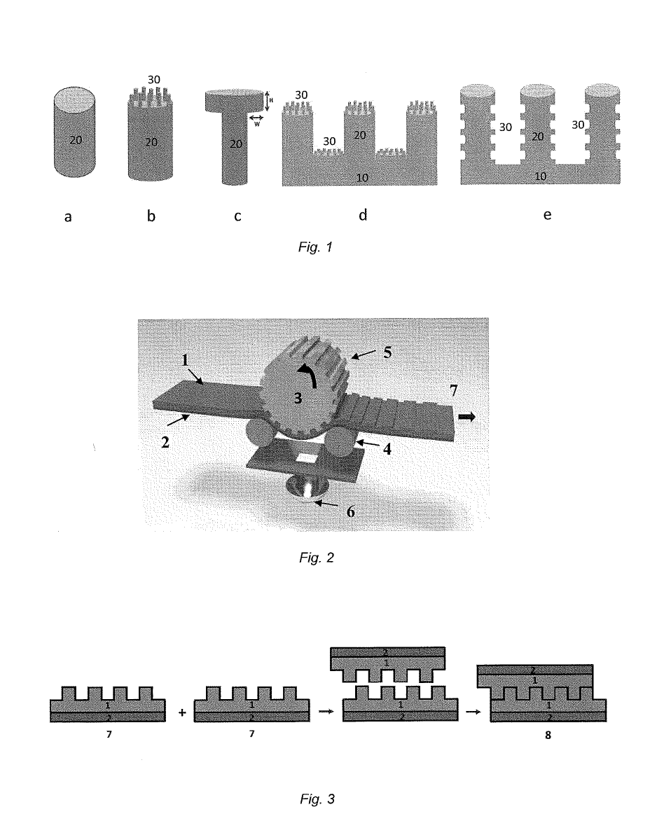

FIG. 1 illustrates some of the preferred shapes of the fixing elements (20) protruding from the substrate (10) and showing where hierarchical structures (30) may be.

Shape (a) of the fixing element in FIG. 1 is a pillar (cylinder), having a diameter preferably from 120 μm-400 μm, height preferably from 200 μm-500 μm and spacing between the pillars from 100 μm-400 μm. Shape (a) pillars have preferably controlled side wall slope and roughness.

Shape (b) of the fixing element in FIG. 1 is a pillar (cylinder) having hierarchal structures at the top surface of the pillar. Shape (b) has a diameter preferably from 120 μm-400 μm, height preferably from 200 μm-500 μm and spacing between the pillars from 100 μm-400 μm. Hierarchical structures of shape b have preferably a diameter preferably from 10 μm-40 μm, height preferably from 20 μm-50 μm and spacing between the pillars from 10 μm-40 μm.

Shape (c) of the fixing element in FIG. 1 is a pillar with overhanging structure. Shape (c) has a diameter preferably from 120 μm-400 μm, height preferably from 200 μm-500 μm and spacing between the pillars from 100 μm-400 μm. Overhanging structures of shape c have preferably a width (w) preferably from 5 μm-15 μm and height (h) preferably from 20 μm-50 μm.

Shape (d) of the fixing element in FIG. 1 is a pillar (cylinder) having hierarchal structures at the top surface of the pillar and on the surface between the pillars. Shape (d) has a diameter preferably from 120 μm-400 μm, height preferably from 200 μm-500 μm and spacing between the pillars from 100 μm-400 μm. Hierarchical structures of shape b have preferably a diameter preferably from 10 μm-40 μm, height preferably from 20 μm-50 μm and spacing between the pillars from 10 μm-40 μm.

Shape (e) of the fixing element in FIG. 1 is a pillar (cylinder) having hierarchal structures on the side surfaces of the pillar. Shape (e) has a diameter preferably from 120 μm-400 μm, height preferably from 200 μm-500 μm and spacing between the pillars from 100 μm-400 μm. Hierarchical structures of shape b have preferably a diameter preferably from 10 μm-40 μm, height preferably from 20 μm-50 μm and spacing between the pillars from 10 μm-40 μm.

In one preferred embodiment a hierarchical structures (30) are provided on at least parts of the outer surface of at least one fixing element (20) and/or on at least parts of the surface of the substrate (10) adjacent to at least one fixing elements.

In another preferred embodiment said hierarchical structures (30) are provided on at least parts of the outer surface of each fixing element (20) and/or on at least parts of the surface of the substrate (10) adjacent to each fixing elements.

In yet another preferred embodiment said hierarchical structures (30) are provided on top of at least one fixing element (20) and/or on at least parts of the surface of the substrate (10) adjacent to at least one fixing elements.

The substrate and the plurality of the fixing elements according to the present invention are formed from a photo-curable adhesive composition. The suitable photo-curable adhesive composition according to the present invention must fulfil the requirements of the UV assisted Roll-To-Roll or Nanolmprint Lithography manufacturing processes and targeted reclosable fastener system requirements.

The photo-curable adhesive composition according to the present invention comprises component A: a (meth)acrylate monomer or oligomer comprising at least two (meth)acrylate groups and having an average molecular weight M_{w} from 700 g/mol to 7000 g/mol, component B: a (meth)acrylate monomer or oligomer comprising at least two (meth)acrylate groups and having an average molecular weight M_{w} equal or greater than 150 g/mol and less than 700 g/mol, component C: a photoinitiator, and component D: a polythiol.

The suitable photo-curable adhesive according to the present invention is solvent free. Presence of a solvent(s) in a composition would create an extra solvent elimination step before the UV-curing.

Component A

The photo-curable adhesive composition according to present invention comprises a component A: a (meth)acrylate monomer or oligomer comprising at least two (meth)acrylate groups. Component A has an effect on mechanical properties of the adhesive composition. Suitable (meth)acrylate monomers or oligomers for use herein have an average molecular weight M_{w} from 700 g/mol to 7000 g/mol, preferably from 1000 g/mol to 5000 g/mol.

This particular molecular weight range provides required mechanical properties: the system is robust enough, in order to prevent delamination, but also robust enough to withstand several attach and detach cycles.

At least two (meth)acrylate groups also provides required mechanical properties: the system is robust enough, in order to prevent delamination, but also robust enough to withstand several attach and detach cycles.

Suitable (meth)acrylate monomers or oligomers for use in the present invention are preferably selected from the group consisting of caprolactone-modified dipentaerythritol hexa(meth)acrylate, polyethylene glycol di(meth)acrylate, polypropylene glycol di(meth)acrylate and caprolactone-modified tris(acryloxyethyl)isocyanurate, aliphatic urethane acrylate oligomer and mixtures thereof.

In addition to above, suitable (meth)acrylate monomers or oligomers for use in the present invention are also (meth)acrylic oligomers having at least one (meth)acryloyl group selected from the group consisting of epoxy acrylate, urethane acrylate, polyester acrylate, polyol acrylate, polyether acrylate, silicone resin acrylate, melamine acrylate and mixtures thereof.

Preferred (meth)acrylate monomers or oligomers are aliphatic urethane acrylate oligomers. They are preferred because they allow high values of tensile and elongation.

Commercially available example of suitable (meth)acrylate oligomer for use herein is for example aliphatic urethane acrylate oligomer CN 9007 from Sartomer.

The photo-curable adhesive composition according to present invention comprises a component A from 40% to 88% by weight of the total weight of the composition, preferably from 50% to 88%, and most preferably from 60% to 88%.

Selected range of component A provides the balance between the viscosity and mechanical properties. More than 88% of component A by weight of the total weight of the composition would lead too high viscosity for the processes according to the present invention. On the other hand, quantities below 40% of component A by weight of the total weight of the composition would lead too brittle structure of the substrate and the fixing elements.

Component B

The photo-curable adhesive composition according to present invention comprises a component B: a (meth)acrylate monomer or oligomer comprising at least two (meth)acrylate groups. Component B has an effect on mechanical properties of the adhesive composition. Suitable (meth)acrylate monomers or oligomers have an average molecular weight M_{w} equal or greater than 150 g/mol and less than 700 g/mol, preferably from 180 g/mol to 400 g/mol.

This particular molecular weight range provides required mechanical properties: the system is robust enough, in order to prevent delamination, but also robust enough to withstand several attach and detach cycles.

At least two (meth)acrylate groups also provides required mechanical properties: the system is robust enough, in order to prevent delamination, but also robust enough to withstand several attach and detach cycles.

Suitable (meth)acrylate monomers or oligomers are preferably selected from the group consisting of 1,4-butanediol di(meth)acrylate, dicyclopentanyl di(meth)acrylate, ethylene glycol di(meth)acrylate, dipentaerythritol hexa(meth)acrylate, caprolactone-modified dipentaerythritol hexa(meth)acrylate, 1,6-hexanediol di(meth)acrylate, neopentyl glycol di(meth)acrylate, pentaerythritol tri(meth)acrylate, polyethylene glycol di(meth)acrylate, polypropylene glycol di(meth)acrylate, tetraethylene glycol di(meth)acrylate, trimethylolpropane tri(meth)acrylate, tris(acryloxyethyl)isocyanurate, caprolactone-modified tris(acryloxyethyl)isocyanurate, tris(methacryloxyethyl)isocyanurate, tricyclodecane dimethanol di(meth)acrylate and mixtures thereof. Preferably (meth)acrylate monomers or oligomers are selected from the group consisting of 1,4-butanediol di(meth)acrylate, 1,6-hexanediol di(meth)acrylate, tetraethylene glycol di(meth)acrylate and mixtures thereof.

Preferred (meth)acrylate monomers or oligomers are desired because of the mechanical properties they provide, indeed, they offer ideal crosslinking density and robustness for the fixing elements.

Commercially available examples of suitable (meth)acrylate monomer or oligomer are for example 1,6-hexanediol diacrylate under the trade name SR 238 from Sartomer, 1,4-butanediol dimethacrylate under the trade name SR 214 from Sartomer and tetraethylene glycol diacrylate under the trade name SR 268G from Sartomer.

The photo-curable adhesive composition according to present invention comprises a component B from 2% to 50% by weight of the total weight of the composition, preferably from 2% to 40%, and most preferably from 2% to 30%.

Selected range of component B provides the balance between viscosity and mechanical properties. More than 50% of component B by weight of the total weight of the composition would lead to a brittle structure of the substrate and the fixing elements. On the other hand, quantities below 2% of component B by weight of the total weight of the composition would cause too high viscosity for the processes according to the present invention. In addition, too low quantities would lead to insufficient level of crosslinking.

Component C

The photo-curable adhesive composition according to present invention comprises a component C: a photoinitiator. A photoinitiator is used to promote polymerisation reaction.

Preferably the photoinitiator is selected from the group consisting of benzophenones, α-hydroxyketones, benzyldimethyl-ketals, α-aminoketones, phenylglyoxolates, mono- or bis-acylphosphines, metallocenes and mixtures thereof, preferably selected from the group consisting of 2-hydroxy-2-methyl-1-phenyl-1-propanone, α,α-dimethoxy-α-phenylacetophenone, 2-methyl-1-(4-(methylthio)phenyl)-2-(4-morpholinyl)-1-propanone, oxy-phenyl-acetic acid 2-(2-oxo-2phenyl-acetoxy-ethoxy)-ethyl ester, diphenyl(2,4,6-trimethylbenzoyl)phosphine oxide, bis(beta-5-2,4-cyclopentadien-1-yl)bis[2,6-difluoro-3-(1H-pyrrol-1-yl)phenyl]titanium and mixtures thereof and more preferably selected from bis(2,4,6-trimethylbenzoyl)-phenylphosphineoxide and 2-hydroxy-2-methyl-1-phenyl-propanone and mixtures thereof.

Preferred photoiniators provide ideal balance between surface curing and depth curing.

Commercially available examples of suitable photoinitiators are for example bis(2,4,6-trimethylbenzoyl)-phenylphosphineoxide under the tradename Irgacure 819 and 2-hydroxy-2-methyl-1-phenyl-propanone under the tradename Darocur 1173 both are available from Ciba Specialty Chemicals.

The photo-curable adhesive composition according to present invention comprises a component C from 0.05 to 20 parts per hundred parts of resin, preferably from 0.1 to 15 parts per hundred parts of resin, more preferably from 0.1 to 10 parts per hundred parts of resin, and most preferably from 1 to 5 parts per hundred parts of resin.

Less than 0.05 phr of component C in the composition according to the present invention, the composition would not cure. On the other hand, more than 20 phr of component C would not add any value, due the fact that lower quantity provides full cure and the curing speed is fast enough. Moreover, photoinitiators are generally very expensive, and therefore, it is preferred to optimise the photoinitiator quantity in the composition as low as possible.

Component D

The photo-curable adhesive composition according to present invention comprises a component D: a polythiol.

By the term polythiol is meant herein ligands having multiple thiol groups in the molecular structure. Furthermore, said polythiols used in the present invention have multiple functions (to act as a precursor, solvent and stabilizer), and therefore, can be considered as multifunctional polythiols. In other words the polythiols used in the present invention are used as multifunctional reagents.

Polythiol component is required in order to overcome the oxygen inhibition issue, as the photo-curable formulation according to the present invention is to be processed in the ambient conditions. By the oxygen inhibition issue is meant herein the issue relating to the fact that UV-curable acrylics are inhibited by oxygen during curing, and therefore, leading to the material, which is not fully cured on the surface (tacky) after the full curing time.

Preferably, a polythiol is primary and/or secondary thiol, more preferably polythiol is selected from the group consisting of 2,5-hexanedithiol, 2,9-decanedithiol, ethylene glycol bis(3-mercapto butyrate), butanediol bis(3-mercapto butyrate), octanediol bis(3-mercapto butyrate), trimethylolpropane tris(3-mercapto butyrate), pentaerythritol tetrakis(3-mercapto butylate), ethylene glycol bis(2-mercaptopropionate), butanediol bis(2-mercaptopropionate), octanediol bis (2-mercaptopropionate), trimethylolpropane tris(2-mercaptopropionate), pentaerythritol tetrakis(2-mercaptopropionate), ethylene glycol bis(2-mercaptoisobutyrate), butanediol bis(2-mercaptoisobutyrate), octanediol bis(2-mercaptoisobutyrate), trimethylolpropane tris(2-mercaptoisobutyrate), pentaerythritol tetrakis(2-mercaptoisobutyrate), pentaerythritol tetrakis (3-mercaptopropionate); trimethylolpropane tris (3-mercaptopropionate), tris[2-(3-mercaptopropionyloxy) ethyl] isocyanurate, ethylene glycol bis(3-mercaptovalerate), butanediol bis(3-mercapto valerate), octanediol bis(3-mercapto valerate), trimethylolpropanetris (3-mercapto valerate), pentaerythritol tetrakis(3-mercapto valerate), 1,4-bis(1-mercaptoethyl)benzene, (2-mercaptoethyl) benzene, phthalic acid bis(2-mercaptoethyl ester), phthalic acid bis(2-mercaptopropanyl ester), phthalic acid bis(2-mercaptobutanyl ester), ethylene glycol bis(3-mercapto butyrate), butanediol bis(3-mercapto butyrate), octanediol bis(3-mercapto butyrate), trimethylolpropane tris(3-mercapto butyrate), pentaerythritol tetrakis(3-mercapto butyrate), ethylene glycol bis(2-mercaptoisobutyrate), butanediol bis(2-mercaptoisobutyrate), octanediol bis(2-mercaptoisobutyrate), trimethylolpropane tris(2-mercaptoisobutyrate), pentaerythritol tetrakis(2-mercaptoisobutyrate) and mixtures thereof, preferably selected from the group consisting of pentaerythritol tetrakis(3-mercaptoisobutylate), pentaerythritol tetrakis (3-mercaptopropionate) (PETMP), trimethylolpropane tris (3-mercaptopropionate) (TMPMP), Tris[2-(3-mercaptopropionyloxy) ethyl] isocyanurate (TEMPIC) and mixtures thereof. Most preferably polythiol is pentaerythritol tetrakis(3-mercaptoisobutylate).

Pentaerythritol tetrakis(3-mercaptoisobutylate), pentaerythritol tetrakis (3-mercaptopropionate) (PETMP), trimethylolpropane tris (3-mercaptopropionate) (TMPMP) and tris[2-(3-mercaptopropionyloxy) ethyl] isocyanurate (TEMPIC) are preferred polythiols because they have a rapid curing, low odor and they increase the adhesion strength of the (meth)acrylate based formulations towards the plastic substrates.

Commercially available example of suitable polythiol is for example pentaerythritol tetrakis(3-mercaptobutylate) under the trade name Karenz MT™ PE1 available from Showa Denko, pentaerythritol tetrakis (3-mercaptopropionate) under the trade name THIOCURE®PETMP from BRUNO BOCK, Trimethylolpropane tris (3-mercaptopropionate) under the trade name THIOCURE®TMPMP from BRUNO BOCK and tris[2-(3-mercaptopropionyloxy) ethyl] isocyanurate under the trade name THIOCURE®TEMPIC from BRUNO BOCK.

The photo-curable adhesive composition according to present invention comprises a component D from 0.05% to 70% by weight of the total weight of the composition, preferably from 0.1% to 60%, more preferably from 1.0% to 50% and most preferably from 1.0% to 40%.

Selected range of component D provides ideal balance between curing speed, viscosity and mechanical properties. More than 70% of component D by weight of the total weight of the composition would lead to over flexible the structure of the substrate and the fixing elements. On the other hand, quantities below 0.05% of component D by weight of the total weight of the composition would slow down the curing speed. In addition, too low quantities would lead to problems with oxygen inhibition.

Component E

The photo-curable adhesive composition according to present invention may further comprise a component E: monofunctional (methacrylate)monomer. Suitable monofunctional (methacrylate)monomer has an average molecular weight M_{w} up to 500 g/mol.

Component E is used in combination with components A and B, in order to adjust viscosity and/or other physical properties. For example, the glass transition temperature can be influenced by the selection of the monomers of component E. In addition, polarity of the adhesive composition can be influenced via the selection of the monomers of the component E.

In highly preferred embodiment of the present invention, the photo-curable adhesive composition comprises component E.

Preferably the monofunctional (meth)acrylate monomer (component E) is selected from the group consisting of butanediol mono(meth)acrylate, cyclohexyl (meth)acrylate, dicyclopentanyl (meth)acrylate, dicyclopentenyl (meth)acrylate, dicyclopentenyloxyethyl (meth)acrylate, N,N-diethylaminoethyl (meth)acrylate, 2-ethoxyethyl (meth)acrylate, 2(2-ethoxyethoxy)ethyl (meth)acrylate, 2-hydroxyethyl (meth)acrylate, 2-hydroxypropyl (meth)acrylate, caprolactone-modified 2-hydroxyethyl (meth)acrylate, isobornyl (meth)acrylate, lauryl (meth)acrylate, acryloylmorpholine, N-vinylcaprolactam, nonylphenoxypolyethylene glycol (meth)acrylate, nonylphenoxypolypropylene glycol (meth)acrylate, phenoxyethyl (meth)acrylate, phenoxyhydroxypropyl (meth)acrylate, phenoxydiethylene glycol (meth)acrylate, polyethylene glycol (meth)acrylate, polypropylene glycol (meth)acrylate, tetrahydrofurfuryl (meth)acrylate and mixtures thereof, preferably selected from the group consisting of isobornyl (meth)acrylate, 2-hydroxyethyl (meth)acrylate, 2-hydroxypropyl (meth)acrylate, 2(2-ethoxyethoxy)ethyl (meth)acrylate, tetrahydrofurfuryl (meth)acrylate and mixtures thereof.

Preferred monofunctional (methacrylate)monomers promote the adhesion to flexible thermoplastic substrates.

Commercially available examples of suitable monofunctional (methacrylate)monomers are for example isobornyl acrylate under the trade name SR506D from Sartomer and isobornyl methacrylate from Sigma Aldrich.

In one embodiment an adhesive strip according to the present invention comprises a support, a substrate and a plurality of fixing elements protruding from said substrate, wherein said fixing elements and said substrate are formed from a photo-curable adhesive composition comprising component A: a (meth)acrylate monomer or oligomer comprising at least two (meth)acrylate groups and having an average molecular weight M_{w} from 700 g/mol to 7000 g/mol; component B: a (meth)acrylate monomer or oligomer comprising at least two (meth)acrylate groups and having an average molecular weight M_{w} equal or greater than 150 g/mol and less than 700 g/mol; component C: a photoinitiator; and component D: a polythiol (multifunctional thiol).

The photo-curable adhesive composition according to the present invention comprises a component E from 0% to 65% by weight of the total weight of the composition, preferably from 0% to 50%, more preferably from 0.1% to 50, and even more preferably from 0.1% to 45%, and most preferably from 0.1% to 40%.

In the highly preferred embodiment, the photo-curable adhesive composition according to the present invention comprises component A: a (meth)acrylate monomer or oligomer comprising at least two (meth)acrylate groups and having an average molecular weight M_{w} from 700 g/mol to 7000 g/mol; component B: a (meth)acrylate monomer or oligomer comprising at least two (meth)acrylate groups and having an average molecular weight M_{w} greater than 150 g/mol and less than 700 g/mol; component C: a photoinitiator; component D: a polythiol (multifunctional thiol); and component E: a monofunctional (meth)acrylate monomer.

This highly preferred combination provides ideal balance between adhesion, mechanical properties and process conditions. Furthermore, this highly preferred combination provides ideal overall performance, including ideal filling of the cavities of the flexible working stamp suitable for nanoimprint lithography process.

The photo-curable adhesive composition according to the present invention may further comprise addition ingredients selected from the group consisting of pigments, antioxidants and fillers.

The photo-curable adhesive composition according to the present invention has low viscosity preferably from 20 to 50000 mPa·s. Viscosity below 40000 mPa·s is preferred in order to assist in a homogeneous coating during reverse gravure coating method. Viscosity is measured in a Brookfield DV-II+Pro EXTRA viscometer using spindle SC4-27 spindle at 0.5 rpm to 60 rpm at 25° C. and according to ASTM D2983.

The photo-curable adhesive composition according to the present invention has fast UV-light curing time, preferably curing time is less than 1 s. Fast curing time is required to increase the printing speed, and therefore, to increase the throughput of the process.

The photo-curable adhesive composition according to the present invention is preferably in liquid state at the room temperature (about 23° C.). Liquid state is preferred because it simplifies the process according to the present invention by removing requirement of for example pre-bake step.

The photo-curable adhesive composition according to present invention has high adhesion towards the flexible substrate, but low adhesion towards the working stamp.

The photo-curable adhesive composition according to the present invention has Young's Modulus ranges from 1 to 75 N/mm², more preferably from 3 to 45 N/mm².

The photo-curable adhesive composition according to the present invention has tensile strength from 0.3 to 10 N/mm², measured according to ISO 527, more preferably from 0.6 to 7 N/mm².

The photo-curable adhesive composition according to the present invention has tensile elongation from 5 to 100%, more preferably from 9 to 75%.

For the tensile tests the composition according to the present invention were dispensed into a Teflon mould (10×2×25 mm) and allowed to cure in a Loctite UVALOC 1000 Chamber using a mercury vapor lamp. Irradiance on the sample surface was measured with a UV Power Puck high energy UV radiometer (EIT Inc., Sterling, Va.) and was 48.7 (UVA), 33.8 (UVB) mW/cm² respectively.

The mechanical properties of the cured compositions according to the present invention were tested using an Instron 3366 with clamps up to 5000N.

The process to produce the adhesive strip according to the present invention relies on continuous manufacturing process, which is called UV assisted Roll-To-Roll or batch to batch manufacturing process which is called UV assisted Nanolmprint Lithography (UV NIL). These processes are capable of fabricating a flexible reclosable fasteners by using a photo-curable material.

Compared to the ordinary extrusion process, processes according to the present invention do not require cooling time or heating. In addition, the processes according to the present invention allows the fabrication of structures with dimensions down to tens of nanometer, whereas the minimum feature size achievable via extrusion process is in the order of tens of micrometer. Finally, UV assisted Roll-To-Roll process has a higher throughput in comparison to traditional extrusion process.

A continuous process to prepare an adhesive strip according to the present invention comprises steps of:
i) providing a support suitable for nanoimprint lithography processes or roll to roll printing processes (suitable supports have been discussed above);
ii) applying sufficient amount of the photo-curable adhesive composition according to the present invention at least part of the support provided on step (i);
iii) providing a stamp suitable for nanoimprint lithography processes and imprinting the photo-curable adhesive composition applied to the support in step (ii) with the stamp or providing a flexible working stamp around rotating metallic roll and printing the photo-curable adhesive composition applied to the support in step (ii) with the flexible working stamp;
iv) simultaneously with the step (iii), the support is irradiated by using UV light; and
v) said support containing the cured structured adhesive composition is de-moulded from the stamp or from the flexible working stamp.

By the term “sufficient” is meant herein a quantity of a photo-curable adhesive composition according to the present invention that is visually required to obtain homogeneous coating for the desired area.

By “cured structured adhesive composition” is meant herein a substrate and a plurality of fixing elements protruding from said substrate.

Advantage of the process according to the present invention versus traditional extrusion process is the flexibility and versatility of the process. Contrary to extrusion, using the process according to the present invention it is possible to tune the mechanical properties of the final product by simply adding another chemical component into the photocurable formulation, or even only varying the content of the existing components. No changes are required in the equipment set-up when processing a composition presenting different mechanical properties as opposed to extrusion or injection moulding.

FIG. 2 illustrates one embodiment of the process according to the present invention, wherein the UV-curable compostion according to the present invention (1) is applied on top of the flexible support (2). Flexible support (2) and UV-curable composition (1) are supported by supporting rolls (4) and moved through a roll (3) having a flexible working stamp (5) suitable for nanoimprint lithography process and imprinting the photo-curable adhesive composition (1). Simultaneously to the imprinting UV-light source (6) is provided underneath the flexible support and UV-curable composition (1) is cured. And an adhesive strip (7) according to the present invention is formed.

In one embodiment, an inkjet dispenser may be installed above the roll (3). The inkjet dispenser is used to dispense additional UV-curable composition according to the present invention to prefill the cavities of the flexible working stamp. This is to increase the filling level of the cavities of the flexible working stamp.

The produced adhesive strip can be collected and stored in rolls, whose width can vary from 50 millimeter to 3 meter.

The printing speed in the process according to the present invention is from 0.1 m/min to 20 m/min, preferably from 0.5 m/min to 20 m/min.

The flexible working stamp

The flexible working stamp used in the process according to the present invention may be fabricated from the master stamp (generally in silicon) using a nickel electroforming process, or a casting process in the case of polymerized moulds or an imprint process in the case of polymer sheet moulds.

Nickel electroforming produces high strength metallic stamp, which is resistant to defect accumulation and the process itself does not damage the master stamp pattern. The nickel plate in a stamp is about 100 μm thick, but thin enough to be flexible. The drawback of these nickel stamps is that they raise the overall manufacturing cost and that they are not flexible enough during the de-moulding process

In addition, the nickel electroformed moulds can be replicated again by metal-on-metal electroforming so that the master stamp does not need to be employed for all replication cycles. However, the technique suffers from resolution and aspect ratio limitations.

Replication by casting is perhaps the simplest and most inexpensive mould replication approach because no special equipment is required and because the replication process is typically achieved through polymerization chemistry. Casting techniques generally do not involve the application of pressure against the master stamp, and thus, the risk of damage to the master stamp is minimal. A wide variety of prepolymer resins and polymer solutions can be used in the casting, including low surface energy materials like polydimethylsiloxane (PDMS) and fluoropolymers like Teflon.

The flexible working stamp for the use in the process according to the present invention is prepared by casting technique.

The adhesive strip according to the present invention can be used as a reclosable fastener. By the term “reclosable” is meant herein that the fastener is capable of being tightly closed again after opening.

One embodiment of the present invention is directed to a reclosable male-to-male fastener comprising two adhesive strips according to the present invention. The fixing elements in the adhesive strip are patterned on a thermoplastic flexible support without using an adhesion promoter.

The reclosable fastener is obtained putting into contact two adhesive strips according to the present invention, containing the same fixing structures (male-to-male configuration), as shown in FIG. 3. FIG. 3 illustrates how two adhesive strips according to the present invention, comprise flexible substrate (1) at the bottom and UV-curable adhesive composition according to the present invention forms substrate and plurality of fixing elements (2) at the top of the flexible substrate (1) forms the reclosable male-to-male fastener (3) according to the present invention.

The reclosable fasteners according to the present invention represent a versatile technology that can be potentially implemented into new applications, mostly related but not limited to flexible packaging, temporary attachment or dry adhesive.

In one embodiment, the adhesive strip according to the present invention may be directly fabricated onto the flexible packaging. Some potential applications are replacement of the adhesive label existing in a tissue pack; in tobacco flexible packaging or closing system for food packaging. The adhesive strips according to the present invention may be applied on demand on any flexible substrate by simply putting a pressure-sensitive adhesive (PSA) on the back of the flexible material.

In more in general, the reclosable fasteners according to the present invention (male-to-male configuration) may be employed each time when a temporary attachment is required. Some non-limiting examples are for decoration wallpaper, temporary display, etc.; as a reclosable fastener for textile and synthetic fabrics or as a dry attachment system in environment wherein liquid or tacky adhesives cannot be employed.

In one embodiment the adhesive strips according to the present invention are formed (cured) directly on top of the support of interest—i.e. directly on the packaging. For example, a tissue pack that has the adhesive strip according to the present invention formed directly on the packaging, or a nappy where the adhesive strip according to the present invention is formed directly on the attaching stripes of the nappy.

In another embodiment the adhesive strips according to the present invention are formed (cured) on a flexible support—subsequently at the back of that support an adhesive is applied (i.e. PSA, hot-melt, etc.) enabling the use of the system as a fixing pad.

In another embodiment, the adhesive strips according to the present invention are formed (cured) on a flexible support and subsequently mechanically attached to the substrate of interest (i.e. sewn, stitched, etc.).

The reclosable fasteners according to the present invention show excellent properties: the shear and peel force can be tuned and controlled without any force ripple during the attaching and separation step; shear-peel capability even after bending; random attachment in terms of direction; long life time cycle's (multiple opening and closing).

### EXAMPLES

### Example 1

### Preparation of the Flexible Working Stamp

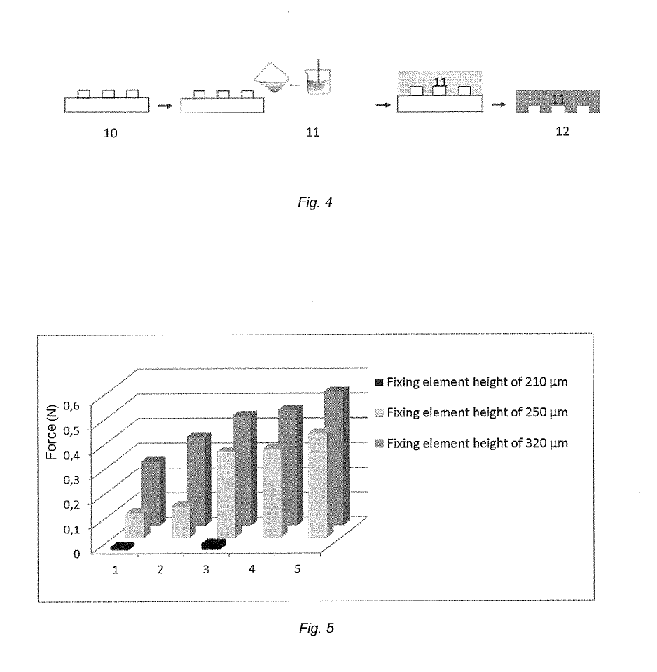

Several steps are required in order to produce the flexible working stamp (as shown in FIG. 4), which is then wrapped around a metallic roll (3) and installed into the process equipment. FIG. 3 illustrates how the flexible working stamp is prepared. The pillar shaped structures are fabricated on a silicon (Si) master stamp (10) by means of photolithography and deep reactive ion etching techniques. The master stamp (10) is replicated into a polydimethylsiloxane (PDMS) material (11) to produce working stamp (12) for use in the process according to the present invention.

The replication process was performed by using Sylgard 184 kit of PDMS, composed by a curing agent and a base. A liquid mixture containing the base and the reactive agent was mixed in a ratio of 1:10 respectively. PDMS mixture was poured into pre-patterned Si master stamp and the assembly is placed into an oven at 80° C. for 4 hours. This time is necessary in order to get a soft and flexible stamp with Young's modulus lower than 2 MPa. Prior pouring PDMS solution onto the Si master stamp the master stamp was coated with an anti-adhesion silane layer to help promote the release of the PDMS from the Si master stamp.

### Example 2

### Preparation of Photo-Curable Formulation According to the Present Invention

The components were added into 125 ml HDPE Brown bottle, in the following order: Component A, Component B, Component E, Component D and Component C. Subsequently 20 phr of ceramic microgrinding beads Zirmil®Y 0.2 mm were added. Subsequently all ingredients were mixed by using a Thinky, Awatory Rentaro AR-250 speed mixer for 4 minutes at 2000 rpm. Presence of bubbles in the composition should be avoided in order to obtain reliable mechanical properties and to avoid sample breaking during the curing process.

The composition is solvent free and it can be processed in the ambient conditions and presence of oxygen without any issues related to oxygen inhibition.

| | Ex. 2a | Ex. 2b | Ex. 2c | Ex. 2d | Ex. 2e | Ex. 2f | Ex. 2g | Ex. 2h |
|---|---|---|---|---|---|---|---|---|
| Component A | 90% | 30% | 60% | 95% | 70% | 80% | 50% | 40% |
| CN9007 | | | | | | | | |
| Component B | 8% | 68% | 38% | 3% | 10% | 10% | 10% | 10% |
| SR 238 | | | | | | | | |
| Component D | 2% | 2% | 2% | 2% | 10% | 10% | 10% | 10% |
| KARENTZ | | | | | | | | |
| PE1 | | | | | | | | |
| Component C | 1.8 phr | 1.8 phr | 1.8 phr | 1.8 phr | 1.8 phr | 1.8 phr | 1.8 phr | 1.8 phr |
| Darocur 1173 | | | | | | | | |
| Component C | 0.2 phr | 0.2 phr | 0.2 phr | 0.2 phr | 0.2 phr | 0.2 phr | 0.2 phr | 0.2 phr |
| Irgacure 819 | | | | | | | | |
| Component E | 0 | 0 | 0 | 0 | 10% | 0 | 30% | 40% |
| IBOA | | | | | | | | |
| Viscosity | 36300 | 45 | 1165 | 95750 | 6050 | 17800 | 510 | 310 |
| | mPas | mPas | mPas | mPas | mPas | mPas | mPas | mPas |

CN9007 Oligomer from Sartomer, SR 238 from Sartomer, KARENTZ PE1 from Showa-Denko, Darocur 1173 from Sigma-Aldrich, 1130A from Sigma Aldrich and Irgacure 819 from Ciba Specialty Chemicals.

T-peel and dynamic tensile shear measurements were performed by using Instrom 3366 equipment. T-peel test was carried out according to the ASTM D1876 with a separation speed of 200 mm/min and samples with 6 cm×2.5 cm of active area. Dynamic tensile shear tests were performed according to the ISO 4587 with a separation speed of 2 mm/min and sample contact area of 1 cm×2.5 cm.

### Example 3

### T-Peel Test Measurements of Pillar Shaped Fixing Elements

Several parameters were considered in order to evaluate their impact on peel performances. These were: a) the thickness of the PET support; b) adhesion treatment on PET support; c) the substrate thickness after the imprinting process. The substrate thickness can be accurately tuned by increasing or decreasing the support thickness, by increasing or decreasing the viscosity of the composition.

FIG. 5 illustrates T-Peel test results of pillar shaped fixing elements according to the present invention.

PET support of sample 1 is 100 μm thick, and there is no adhesion treatment and the substrate thickness is 100 μm. PET support of sample 2 is 100 μm thick, and there is no adhesion treatment and the substrate thickness is 15 μm. PET support of sample 3 is 50 μm thick, and there is no adhesion treatment and the substrate thickness is 50 μm. PET support of sample 4 is 50 μm thick, and there is adhesion treatment on a surface and the substrate thickness is 50 μm. PET support of sample 5 is 50 μm thick, and there is no adhesion treatment and the substrate thickness is 15 μm.

Fixing elements, which were tested had heights 210 μm (210 μm deep; 120 μm diameter and 90 μm distance between the pillars), 250 μm (250 μm deep; 250 μm diameter and 210 μm distance between the pillars) and 320 μm (320 μm deep; 300 μm diameter and 360 μm distance between the pillars). Fixing elements and substrate were made of composition of example 2a. General shape of the fixing elements is illustrated in FIG. 1, shape a.

It was noticed that the peel performances of the fixing elements can be adjusted by optimising thickness of the substrate, height of the fixing elements and the surface treatment. The results in FIG. 5 show that the peel force can be increased in the following case: a) increasing the pillar high; b) decreasing the thickness of the substrate; c) with thinner support; d) when an adhesion treatment is applied on the support surface.

### Example 4

### Dynamic Tensile Shear Test Measurements of Pillar Shaped Fixing Elements According to the Present Invention

Several parameters were considered in order to evaluate their impact on peel performances. These were: a) the thickness of the PET support; b) adhesion treatment on PET support; c) the substrate thickness after the imprinting process. The thickness of the substrate can be accurately tuned by increasing or decreasing the thickness of the support, by increasing or decreasing the viscosity of the composition.

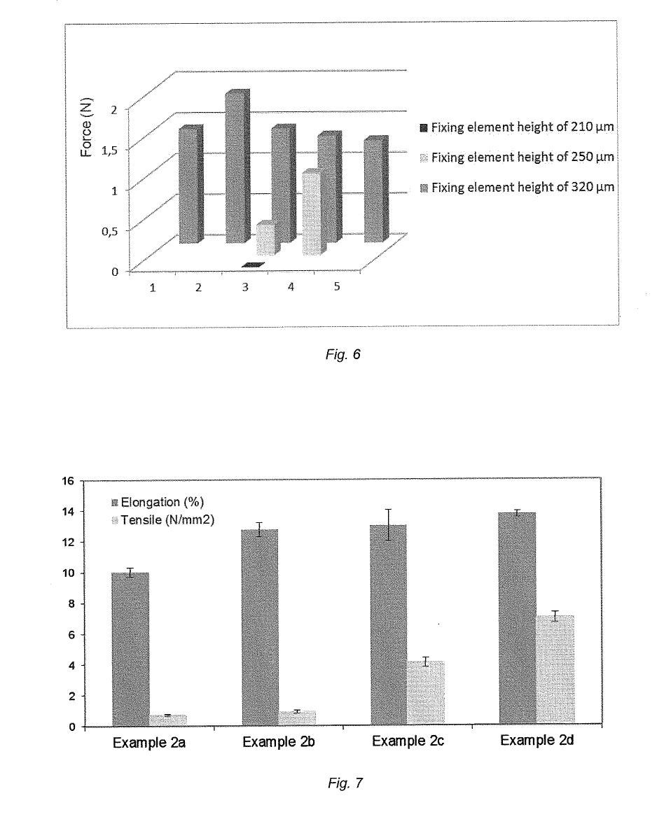

FIG. 6 illustrates a dynamic tensile shear test results of pillar shaped fixing elements according to the present invention.

PET support of sample 1 is 100 μm thick, and no adhesion treatment is applied and thickness of the substrate is 100 μm. PET support of sample 2 is 100 μm thick, and no adhesion treatment is applied and thickness of the substrate is 15 μm. PET support of sample 3 is 50 μm thick, and no adhesion treatment is applied and thickness of the substrate is 50 μm. PET support of sample 4 is 50 μm thick, and adhesion treatment is applied on the surface and thickness of the substrate is 50 μm. PET support of sample 5 is 50 μm thick, and no adhesion treatment is applied and thickness of the substrate is 15 μm.

Fixing elements, which were tested had heights 210 μm, 250 μm and 320 μm (same dimensions applies as in example 3 above). Fixing elements and substrate were made of composition of example 2a. General shape of the fixing elements is illustrated in FIG. 1, shape a.

The results in FIG. 6 demonstrates that for pillars with a height lower than 250 μm the shear force is minimum. In contrast fixing elements with 320 μm height present the high shear force values—ranging between 1.3 and 1.7 N. It was also noted that the substrate thickness and the adhesion surface treatment does not provide a clear impact on the shear force.

### Example 5

### Tuning of Mechanical Properties by Varying the Content of the Chemical Components (Compositions A-D)

FIG. 7 illustrates mechanical properties (tensile strength and elongation) for compositions 2a-2d.

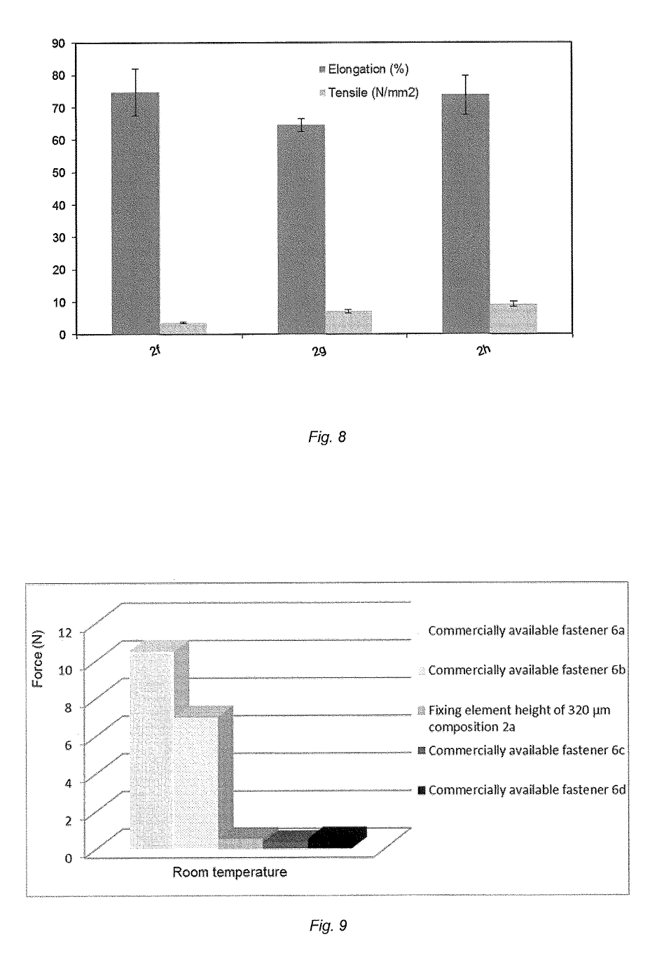

FIG. 8 illustrates mechanical properties (tensile strength and elongation) for compositions 2f-2h.

Contrary to extrusion, using the process according to the present invention it is possible to tune the mechanical properties of the final product by simply modifying the chemical composition in the photo-curable formulation, or even only varying the content of the existing components. No changes are required in the equipment set-up when processing a formulation presenting different mechanical properties.

### Example 6

### Comparative T-Peel Test

Comparative T-peel test was done to compare the performance of 320 μm fixing elements according to the present invention with other commercially available male-to-male and male-to-female fasteners. Commercially available product (6a) contains mushroom shaped elements with height of about 1.5 mm and a cap 1 mm wide. Commercially available product (6b) having mushroom shaped elements with height of about 1.4 mm and a cap 1.2 mm wide. Another commercially available fastener (6c) contains arrow shaped elements with a rounded tip having height of about 500 μm and a tip 400 μm wide. Yet another commercially available fastener (6d) contains hook shaped elements with height of about 1.1 mm and a cap 800 μm wide.

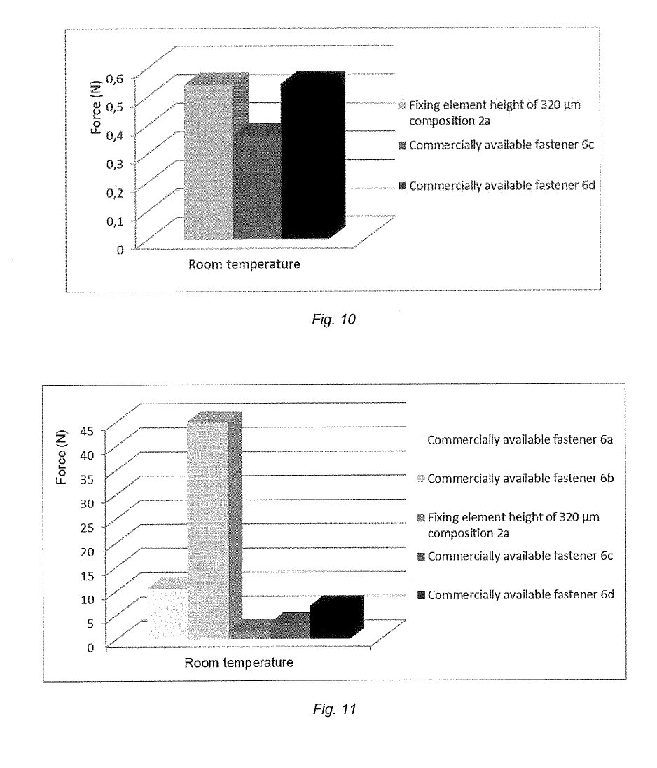

FIG. 9 illustrates the test results and FIG. 10 illustrates enlargement of FIG. 9 indicating that 320 μm fixing elements according to the present invention (320 μm deep, 300 μm diameter and 360 μm distance between the pillars; fixing elements and substrate were made of composition of example 2a; general shape of the fixing elements is illustrated in FIG. 1, shape (a) have comparable performances to commercial fasteners having fixing elements with physical dimensions at micrometer scale.

### Example 7

### Comparative Dynamic Tensile Shear Test

Comparative dynamic tensile shear test was done to compare the performance of 320 μm fixing elements according to the present invention (320 μm deep, 300 μm diameter and 360 μm distance between the pillars; fixing elements and substrate were made of composition of example 2a; general shape of the fixing elements is illustrated in FIG. 1, shape (a) with other commercially available male-to-male and male-to-female fasteners. Commercially available fastener 6a contains mushroom shaped elements with height of about 1.5 mm and a cap 1 mm wide. Commercially available fastener 6b contains mushroom shaped elements with height of about 1.4 mm and a cap 1.2 mm wide. Commercially available fastener 6c contains arrow shaped elements with a rounded tip having height of about 500 μm and a tip 400 μm wide. Commercially available fastener 6d contains hook shaped elements with height of about 1.1 mm and a cap 800 μm wide.

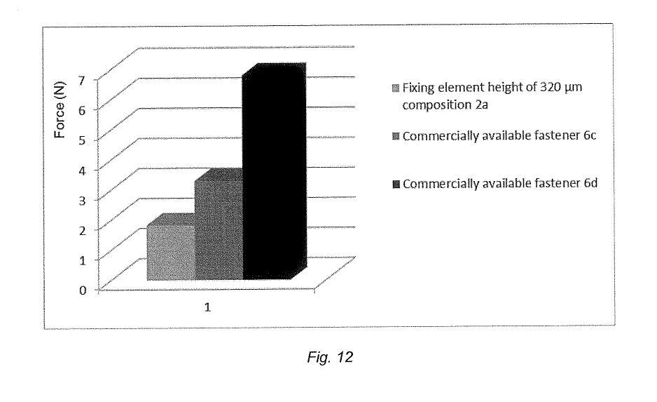

FIG. 11 illustrates the test results and FIG. 12 illustrates enlargement of FIG. 11. FIG. 11 illustrates how 320 μm fixing elements according to the present invention have comparable performances to commercial fasteners having fixing elements with physical dimensions at micrometer scale.

Adhesive strips according to the present invention including a simple pillar configuration and a lower size scale—200 μm gap or more, depending which product it is compared to—is able to get similar or improved performance. The fabrication method is completely different vs. fabrication methods used by the competitors (extrusion)—this enables to provide thinner profiles and smaller structure sizes (more gentle to the customer's touch)—also it provides more flexibility in terms of what resin materials can be used.

1. An adhesive strip comprising a support, a substrate and a plurality of fixing elements protruding from said substrate, wherein said fixing elements and said substrate are formed from a photo-curable adhesive composition comprising
component A: a (meth)acrylate monomer or oligomer comprising at least two (meth)acrylate groups and having an average molecular weight M_{w} from 700 g/mol to 7000 g/mol;
component B: a (meth)acrylate monomer or oligomer comprising at least two (meth)acrylate groups and having an average molecular weight M_{w} equal or greater than 150 g/mol and less than 700 g/mol;
component C: a photoinitiator; and
component D: a polythiol.

2. An adhesive strip according to claim 1, wherein a hierarchical structures are provided on at least parts of an outer surface of at least one fixing element and/or on at least parts of thea surface of the substrate adjacent to at least one fixing element.

3. An adhesive strip according to claim 2, wherein said hierarchical structures are provided on at least parts of the outer surface of each fixing element and/or on at least parts of the surface of the substrate adjacent to each fixing element.

4. An adhesive strip according to claim 1, wherein said fixing elements have a height in the range of 150 um to 1000 μm.

5. An adhesive strip according to claim 1, wherein said fixing elements have a width in the range of 100 μm to 1000 μm.

6. An adhesive strip according to claim 1, wherein said support is a flexible material, semi-flexible material or rigid material.

7. An adhesive strip according to claim 1, wherein said photo-curable adhesive composition further comprises a component E: monofunctional (methacrylate)monomer.

8. An adhesive strip according to claim 1, wherein said components A and B are selected from the group consisting of 1,4-butanediol di(meth)acrylate, dicyclopentanyl di(meth)acrylate, ethylene glycol di(meth)acrylate, dipentaerythritol hexa(meth)acrylate, caprolactone-modified dipentaerythritol hexa(meth)acrylate, 1,6-hexanediol di(meth)acrylate, neopentyl glycol di(meth)acrylate, pentaerythritol tri(meth)acrylate, polyethylene glycol di(meth)acrylate, polypropylene glycol di(meth)acrylate, tetraethylene glycol di(meth)acrylate, trimethylolpropane tri(meth)acrylate, tris(acryloxyethyl)isocyanurate, caprolactone-modified tris(acryloxyethyl)isocyanurate, tris(methacryloxyethyl)isocyanurate, tricyclodecane dimethanol di(meth)acrylate, epoxy acrylate, urethane acrylate, polyester acrylate, polyol acrylate, polyether acrylate, silicone resin acrylate, melamine acrylate and mixtures thereof.

9. An adhesive strip according to claim 1, wherein said component C is selected from the group consisting of benzophenones, α-hydroxyketones, benzyldimethyl-ketals, α-aminoketones, phenylglyoxolates, mono- or bis-acylphosphines, metallocenes and mixtures thereof, preferably selected from the group consisting of 2-hydroxy-2-methyl-1-phenyl-1-propanone, α,α-dimethoxy-α-phenylacetophenone, 2-methyl-1-(4-(methylthio)phenyl)-2-(4-morpholinyl)-1-propanone, oxy-phenyl-acetic acid 2-(2-oxo-2phenyl-acetoxy-ethoxy)-ethyl ester, diphenyl(2,4,6-trimethylbenzoyl)phosphine oxide, bis(beta-5 -2,4-cyclopentadien-1 -yl)bis[2,6-difluoro-3-(1H-pyrrol-1-yl)phenyl]titanium and mixtures thereof and more preferably selected from bis(2,4,6-trimethylbenzoyl)-phenylphosphineoxide and 2-hydroxy-2-methyl-1-phenyl-propanone and mixtures thereof.

10. An adhesive strip according to claim 1, wherein said component D is primary and/or secondary thiol, preferably component D is selected from the list consisting of 2,5-hexanedithiol, 2,9-decanedithiol, ethylene glycol bis(3-mercapto butyrate), butanediol bis(3-mercapto butyrate), octanediol bis(3-mercapto butyrate), trimethylolpropane tris(3-mercapto butyrate), pentaerythritol tetrakis(3-mercapto butyrate), ethylene glycol bis(2-mercaptopropionate), butanediol bis(2-mercaptopropionate), octanediol bis (2-mercaptopropionate), trimethylolpropane tris(2-mercaptopropionate), pentaerythritol tetrakis(2-mercaptopropionate), ethylene glycol bis(2-mercaptoisobutyrate), butanediol bis(2-mercaptoisobutyrate), octanediol bis(2-mercaptoisobutyrate), trimethylolpropane tris(2-mercaptoisobutyrate), pentaerythritol tetrakis(2-mercaptoisobutyrate), pentaerythritol tetrakis (3-mercaptopropionate); trimethylolpropane tris (3-mercaptopropionate), tris[2-(3-mercaptopropionyloxy) ethyl] isocyanurate, ethylene glycol bis(3-mercaptovalerate), butanediol bis(3-mercapto valerate), octanediol bis(3-mercapto valerate), trimethylolpropanetris (3-mercapto valerate), pentaerythritol tetrakis(3-mercapto valerate), 1,4-bis(1-mercaptoethyl)benzene, (2-mercaptoethyl) benzene, phthalic acid bis(2-mercaptoethyl ester), phthalic acid bis(2-mercaptopropanyl ester), phthalic acid bis(2-mercaptobutanyl ester), ethylene glycol bis(3-mercapto butyrate), butanediol bis(3-mercapto butyrate), octanediol bis(3-mercapto butyrate), trimethylolpropane tris(3-mercapto butyrate), ethylene glycol bis(2-mercaptoisobutyrate), butanediol bis(2-mercaptoisobutyrate), octanediol bis(2-mercaptoisobutyrate), trimethylolpropane tris(2-mercaptoisobutyrate), pentaerythritol tetrakis(2-mercaptoisobutyrate) and mixtures thereof.

11. An adhesive strip according to claim 1, wherein said photo-curable adhesive composition comprises a component A from 40% to 88% by weight of the total weight of the composition.

12. An adhesive strip according to claim 1, wherein said photo-curable adhesive composition comprises a component B from 2% to 50% by weight of the total weight of the composition.

13. An adhesive strip according to claim 1, wherein said photo-curable adhesive composition comprises a component C from 0.05 to 20 parts per hundred parts of resin.

14. An adhesive strip according to claim 1, wherein said photo-curable adhesive composition comprises a component D from 0.05% to 70% by weight of the total weight of the composition, preferably from 0.1% to 60%, more preferably from 1.0% to 50% and most preferably from 1.0% to 40%.

15. A reclosable fastener comprising an adhesive strip according to claim 1.

16. A reclosable male-to-male fastener comprising two adhesive strips according to claim 1.

17. A continuous process to prepare an adhesive strip according to claim 1 comprising steps of:
i) providing a support suitable for nanoimprint lithography processes or roll to roll printing processes;
ii) applying sufficient amount of the photo-curable adhesive composition according to claim 1 to at least part of the support provided cutin step (i);
iii) providing a stamp suitable for nanoimprint lithography processes and imprinting the photo-curable adhesive composition applied to the support in step (ii) with the stamp or providing a flexible working stamp around rotating metallic roll and printing the photo-curable adhesive composition applied to the support in step (ii) with the flexible working stamp;
iv) simultaneously with the step (iii), the support is irradiated by using UV light; and
v) said support containing the cured structured adhesive composition is de-moulded from the stamp or from the flexible working stamp.
